(19) United States
(12) Patent Application Publication
(10) Pub. No.: US 2025/0133838 A1
(43) Pub. Date: Apr. 24, 2025

(54) SEMICONDUCTOR DEVICE AND ELECTROSTATIC DISCHARGE CLAMP CIRCUIT

(71) Applicant: TAIWAN SEMICONDUCTOR MANUFACTURING COMPANY LTD., HSINCHU (TW)

(72) Inventors: LI-WEI CHU, HSINCHU CITY (TW); WUN-JIE LIN, HSINCHU CITY (TW)

(21) Appl. No.: 18/489,872

(22) Filed: Oct. 19, 2023

(51) Int. Cl. H01L 27/02

(52) U.S. Cl. CPC H10D 89/819

(57) ABSTRACT

The present disclosure provides a semiconductor device and an electrostatic discharge (ESD) clamp circuit. The semiconductor device includes a first resistance-capacitance (RC) timer circuit, a second RC timer circuit, a voltage pull-down circuit, a voltage pull-up circuit, a discharge circuit, and a discharge control circuit. The first RC timer circuit is coupled between a first power supply voltage and a reference voltage. The second RC timer circuit is coupled between a second power supply voltage and the reference voltage. The voltage pull-up circuit is coupled between the second power supply voltage and the reference voltage through a first resistor. The discharge circuit is coupled between the second power supply voltage and the reference voltage. The discharge control circuit is coupled between a third node and the reference voltage, and controls the discharge circuit using a first voltage generated by the first RC timer circuit.

### BACKGROUND

The present disclosure relates to ESD (electrostatic discharge) protection, and, in particular, to a semiconductor device and ESD clamp circuit for high voltage applications.

An ESD protection device protects electronic circuits from electrostatic discharge (ESD) events, to avoid malfunction or damage thereto. When ESD events occur, a spike voltage can be generated between an external inductive load circuit and a terminal (e.g., gate terminal) of a semiconductor device of a semiconductor wafer. The abnormally high voltage can damage the semiconductor devices of the semiconductor wafer by, for example, blowing out the gate oxide.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1A is a diagram of power clamp circuits with respect to different voltage domains in accordance with an embodiment of the present disclosure.

FIG. 1B is a schematic diagram of a power clamp circuit in accordance with the embodiment of FIG. 1A.

FIG. 2A is a cross section of a transistor 200 in accordance with an embodiment of the present disclosure.

FIG. 2B is a diagram of the transistor 200 in accordance with the embodiment of FIG. 2A.

FIG. 3A is a cross section of a transistor 300 in accordance with another embodiment of the present disclosure.

FIG. 3B is a diagram of the transistor 300 in accordance with the embodiment of FIG. 3A.

FIG. 4A is a schematic diagram of an ESD protection circuit in accordance with an embodiment of the present disclosure.

FIG. 4B is a schematic diagram of the power clamp circuit 410 in accordance with the embodiment of FIG. 4A.

FIG. 5A is a schematic diagram of a power clamp circuit 500 in accordance with an embodiment of the present disclosure.

FIG. 5B is a schematic diagram of a power clamp circuit 510 using high power supply voltage in accordance with an embodiment of the present disclosure.

FIG. 5C is a schematic diagram of a power clamp circuit 510 with noisy power supply voltage in accordance with an embodiment of the present disclosure.

FIG. 6A is a schematic diagram of an ESD clamp circuit 600 in accordance with an embodiment of the present disclosure.

FIG. 6B is a diagram illustrating operations of the ESD clamp circuit 600 in accordance with the embodiment of FIG. 6A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

A clamp circuit as commonly used in ESD protection devices can be referred to as an “ESD power-rail clamp circuit” or “ESD clamp circuit.” The clamp circuit may include an ESD detection circuit and a discharge device. In general, a discharge device can include relatively large transistors, with commensurately large scale in terms of channel width. A transistor of large channel width can be referred to as a “BigFET.” The term “BigFET” can refer to an N-type or P-type transistor having channel width equaling or exceeding 1000 μm.

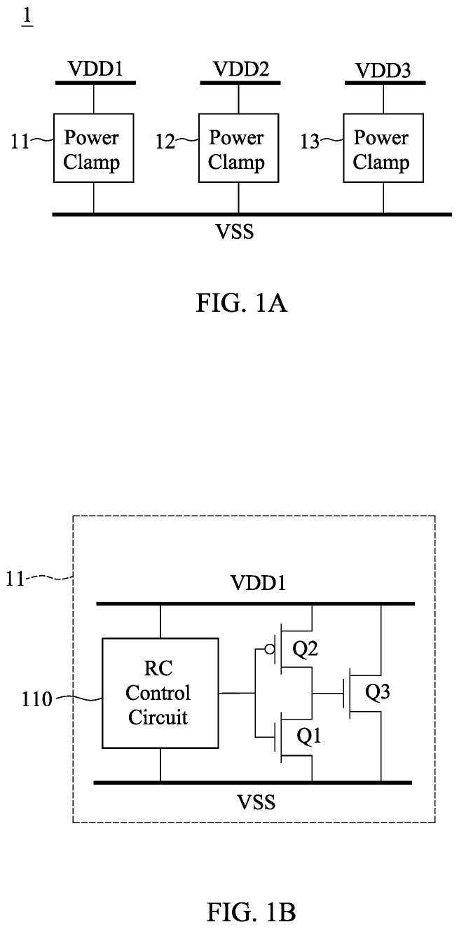

FIG. 1A is a diagram of a semiconductor device 1 in accordance with an embodiment of the present disclosure. FIG. 1B is a schematic diagram of the power clamp circuit 11 in accordance with the embodiment of FIG. 1A. Please refer to FIGS. 1A-1B.

As depicted in FIG. 1A, the semiconductor device 1 may be a CMOS (complementary metal oxide semiconductor) integrated circuit (IC) which includes power clamp circuits 11, 12, and 13 configured to protect internal circuitry (not shown) from ESD events. The power clamp circuit 11 may be disposed between the power rail of the first power supply voltage VDD1 and that of the reference voltage VSS. The power clamp circuit 12 may be disposed between the power rail of the second power supply voltage VDD2 and that of the reference voltage VSS. The power clamp circuit 13 may be disposed between the power rail of the third power supply voltage VDD2 and that of the reference voltage VSS. More specifically, when the semiconductor device 1 includes a mixed-voltage I/O interface with various voltage levels (e.g., VDD1 to VDD3), a respective power clamp circuit may be disposed between the power rail of each voltage domain and that of the reference voltage VSS so as to achieve full-chip ESD protection. In some embodiments, the reference voltage VSS may be a negative voltage. In some embodiments, the reference voltage VSS may be a ground voltage (i.e., 0V).

A schematic diagram of the power clamp circuit 11 is shown in FIG. 1B. For example, the power clamp circuit 11 may include an RC (resistance-capacitance) control circuit 110, and transistors Q1 to Q3. The RC control circuit 110 and the transistors Q1 to Q2 may form a detection circuit 12 electrically coupling/connecting the power rails of the first power supply voltage VDD1 and the reference voltage VSS. The transistor Q3 may be coupled between the first power voltage VDD1, the reference voltage VSS, and node N1, and may function as a discharge circuit. The detection circuit 12 may be configured to generate a signal S1 at node N1 in response to an ESD event. The signal S1 generated by detection circuit 12 may be provided to the gate of the transistor Q3. The signal S1 can trigger a current associated with the ESD event through the transistor Q3.

Specifically, the transistor Q3 may be configured to be turned on and off by the signal S1. When the transistor Q3 is turned on in response to the signal S1, a discharge path P1 can be established between the power rails of the first power supply voltage VDD1 and the reference voltage VSS. When the transistor Q3 is turned off, the power clamp circuit 11 may be in a standby mode since no ESD event occurs.

The power clamp circuits 12 and 13 shown in FIG. 1A may be similar to the power clamp circuit 11. When the power clamp circuits 11 to 13 shown in FIG. 1A are turned off, the semiconductor device 1 may be in a normal operation mode since no ESD event occurs in any of the voltage domains VDD1 to VDD3.

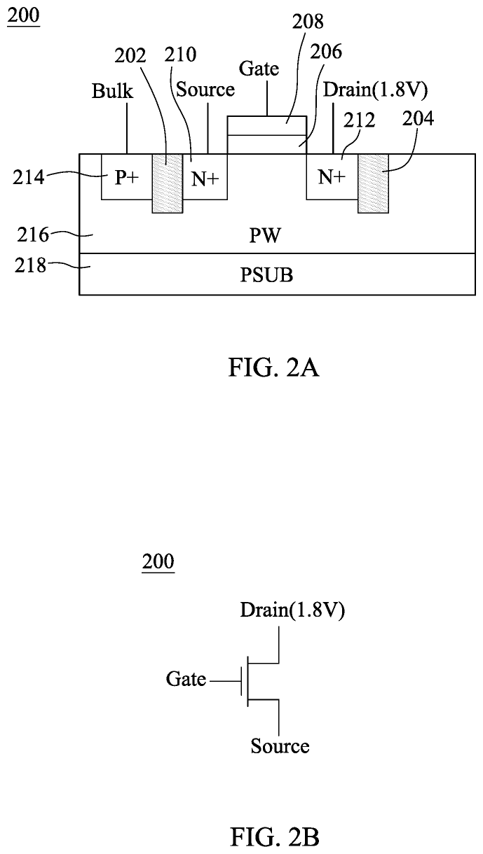

FIG. 2A is a cross section of a transistor 200 in accordance with an embodiment of the present disclosure. FIG. 2B is a diagram of the transistor 200 in accordance with the embodiment of FIG. 2A. Please refer to FIGS. 2A-2B.

In some embodiments, the transistors Q1 and Q3 shown in FIG. 1B may be implemented by the transistor 200 shown in FIG. 2A. For example, the substrate 218 may be or comprise a semiconductor wafer such as a silicon wafer. Alternatively, the substrate 218 may include other elementary semiconductors such as germanium. The substrate 218 may also include a compound semiconductor such as silicon carbide, gallium arsenic, indium arsenide, or indium phosphide. The substrate 218 may include an alloy semiconductor such as silicon germanium, silicon germanium carbide, gallium arsenic phosphide, or gallium indium phosphide. In the present embodiment, the substrate 218 includes a P-type silicon wafer, which may be regarded as a P-type substrate. The well region 216 may be a P-type well region. The bulk terminal 214 and the source terminal 210 may be separated by a shallow trench isolation (STI) region 202.

The transistor 200 may include a gate structure disposed on the well region 216, and the gate structure may include a gate dielectric 206 and a gate electrode 128 disposed on the gate dielectric 206. The gate dielectric 206 includes a silicon dioxide layer formed by thermal oxidation, chemical vapor deposition (CVD), physical vapor deposition (PVD), atomic layer deposition (ALD), or other suitable processes, or combinations thereof. Alternatively, the gate dielectric 206 may include high dielectric-constant (high-k) materials, silicon oxynitride, other suitable materials, or combinations thereof. The gate dielectric 206 may be multilayered of, for example, silicon oxide and high-k material.

The gate electrode 208 may be designed to be coupled to metal interconnects and disposed overlying the gate dielectric 206. The gate electrode 208 may include doped polycrystalline silicon (or polysilicon). Alternatively, the gate electrode 208 may include a metal such as Al, Cu, W, Ti, Ta, TiN, TaN, NiSi, CoSi, other suitable conductive materials, or combinations thereof. The gate electrode 208 may be formed by CVD, PVD, plating, and other acceptable processes. The gate electrode 208 may be multilayered and formed by a multi-step process. In some embodiments, the thickness of the gate dielectric 206 may be designed for 1.8V gate voltage applications.

In some embodiments, the bulk terminal 214 may be a highly doped P-type implanted region (e.g., P+), and the source terminal 210 and the drain terminal 212 may be highly doped N-type implanted region (e.g., N+). In addition, another STI region 204 may be formed next to the drain terminal 212.

In some embodiments, a cross-node voltage between the gate and source of the N-type MOSFET 200 shown in FIG. 2A cannot exceed its nominal voltage, which may be 1.8V for a normal N-type MOSFET (i.e., |VGS|≤1.8V). In addition, the drain terminal 212 may be supplied with a voltage of 1.8V. The symbol of the N-type MOSFET 200 is shown in FIG. 2B.

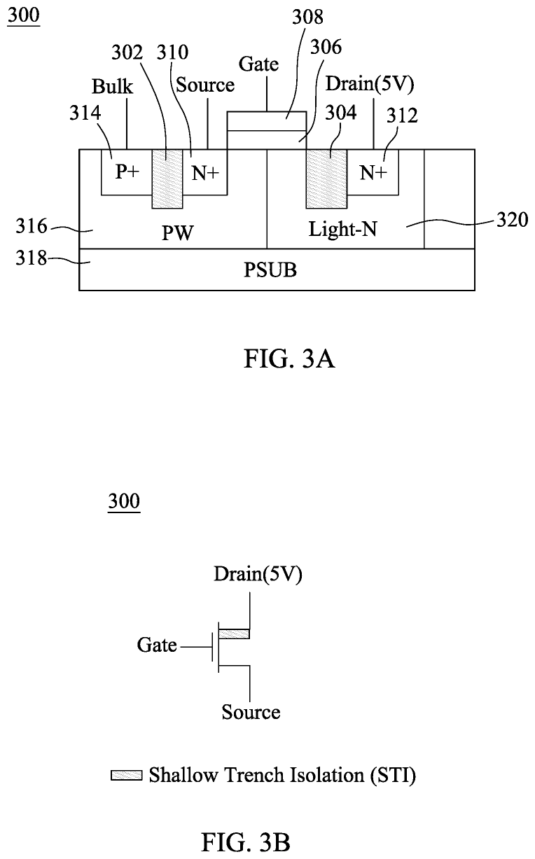

FIG. 3A is a cross section of a transistor 300 in accordance with another embodiment of the present disclosure. FIG. 3B is a diagram of the transistor 300 in accordance with the embodiment of FIG. 3A. Please refer to FIGS. 3A-3B.

While the transistor 200 shown in FIG. 2A may be designed for lower voltage applications (e.g., 1.8V), the transistor 300 shown in FIG. 3A may be designed for higher voltage applications (e.g., 5V). The transistor 300 may be fabricated using laterally diffused MOS (LDMOS) in a CMOS manufacturing process.

For example, a well region 316 and a well region 320 may be formed on the substrate 318, and the well region 316 and the well region 320 may be next to each other. The well region 316 may be a P-type well region, and the well region 320 may be a lightly doped N-type region. The well region 320 may function as a drift region for the n-channel LDMOS device. In some embodiments, the well region 320 may be part of the substrate 318 and form by implantation in absence of an epitaxial layer. The well region 320 may have a N-type dopant such as phosphorus. In some embodiments, the well region 320 may be formed by a plurality of processing steps, whether known or to be developed, such as growing a sacrificial oxide over substrate, opening a pattern for the location of the N-well region, and implanting the impurities.

The transistor 300 may include various isolation structures such as shallow trench isolation (STI) or local oxidation of silicon (LOCOS) formed on the well region 316 or substrate 318 to define and electrically isolate various active regions. As depicted in FIG. 3A, the transistor 300 may include STI region 302 and 304. For example, the STI regions 302 and 304 may include dry etching a trench in a substrate and filling the trench with insulator materials such as silicon oxide, silicon nitride, or silicon oxynitride. The filled trench may have a multi-layer structure such as a thermal oxide liner layer filled with silicon nitride or silicon oxide. In furtherance of the embodiment, the STI structure may be created using a processing sequence such as growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and nitride stripping to remove the silicon nitride.

The doped regions 314 and 310 may be fabricated within the well region 316, and separated by the STI region 302. The doped regions 314 and 310 may be electrically connected to the bulk terminal and the source terminal, respectively. In some embodiments, the doped region 314 may be a highly doped P-type region with P-type impurities (e.g., P+), such as boron. The doped region 310 may be a highly doped N-type region with N-type impurities (e.g., N+), such as phosphorous or arsenic for an n-channel LDMOS device. The STI region 302, and the doped regions 314 and 310 may be surrounded by the well region 316.

The doped region 312 may be fabricated within the well region 320, and a STI region 304 may be fabricated next to the doped region 312 to separate the doped region 312 from the channel (i.e., P-type channel between the doped region 310 and the STI region 304). The doped region 312 and the STI region may be surrounded by the well region 320. In some embodiments, the doped region 312 may be a highly doped N-type region and electrically connected to the drain terminal. The gate oxide 306 may be formed on top of the boundary between the well region 316 and the well region 320, as shown in FIG. 3A. The polysilicon 308 may be formed on the gate oxide 306 and electrically connected to the gate terminal.

Since the transistor 300 is implemented using the LDMOS technique with STI regions (e.g., the STI region 304 next to the doped region 312), the symbol of the transistor 300 may be illustrated with the STI region, as shown in FIG. 3B.

It should be noted that the voltage difference |VDG| between the drain terminal and the gate terminal of the transistor 300 can be limited within 5V (i.e., |VDG|≤5V), and the voltage difference |VDS| between the drain terminal and the source terminal of the transistor 300 can also be limited within 5V (i.e., |VDS|≤5V). However, due to reliability concerns, the gate oxide 306 may be fabricated for 1.8V, and the voltage difference between the gate terminal and the source terminal of the transistor 300 may be limited within 1.8V.

More specifically, the transistors 200 and 300 may exist in the same integrated circuit, and may be fabricated using the same CMOS manufacturing process. In other words, the gate oxide 206 of the transistor 200 and the gate oxide 306 of the transistor 300 in the same integrated circuit may be formed at the same time, so the thickness of the gate oxide 206 may be substantially the same with that of the gate oxide 306. Thus, the voltage tolerance range of the gate oxide 306 may be similar to that of the gate oxide 206, which is 1.8V.

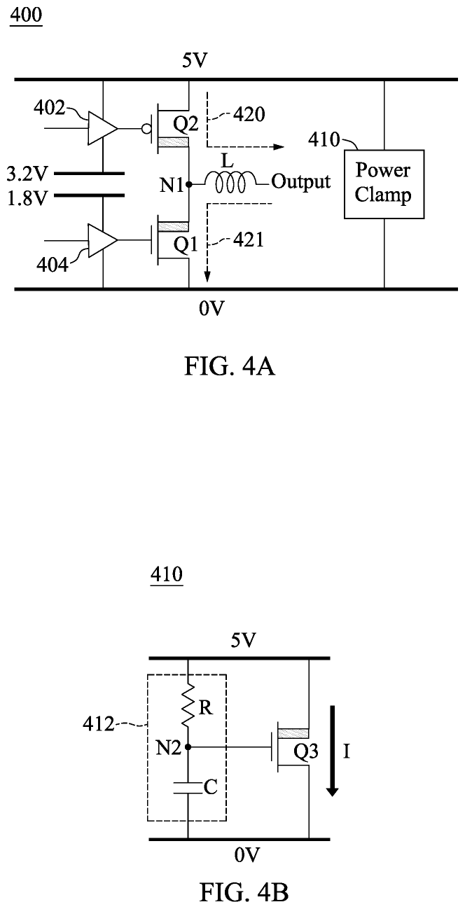

FIG. 4A is a schematic diagram of an ESD protection circuit in accordance with an embodiment of the present disclosure. FIG. 4B is a schematic diagram of the power clamp circuit 410 in accordance with the embodiment of FIG. 4A. Please refer to FIGS. 4A-4B.

In some embodiments, the ESD protection circuit 400 may include a pull-up control logic 402, a pull-low control logic 404, transistors Q1 to Q2, a power clamp circuit 410, and an inductor L. The ESD protection circuit 400 may operate with a power supply voltage of 5V.

The transistor Q2 may be a P-type transistor implemented using the LDMOS technique. The pull-up control logic 402 may be coupled between power rails of voltages of 5V and 3.2V, and may be configured to turn the transistor Q2 on and off. Thus, the voltage difference |VGS| between the gate terminal and the source terminal of the transistor Q2 may be limited within 1.8V, thereby preventing the gate oxide (e.g., fabricated for 1.8V) of the transistor Q2 from being damaged by voltage difference over 1.8V.

The transistor Q1 may be an N-type transistor implemented using the LDMOS technique. The pull-down control logic 404 may be coupled between power rails of voltages of 1.8V and 0V, and configured to turn the transistor Q1 on and off. Thus, the voltage difference |VGS| between the gate terminal and the source terminal of the transistor Q1 may be limited within 1.8V, thereby preventing the gate oxide (e.g., fabricated for 1.8V) of the transistor Q1 from damaged by a voltage difference over 1.8V.

In some embodiments, for electronic circuits operating at high voltages, such as power amplifiers or buck converters, the output terminal thereof may be driven by a large current. In addition, the inductor L may be disposed between node N1 and the output terminal of the ESD protection circuit 400 to stabilize the current from the power rail of the power supply voltage to the output terminal through the transistor Q2 (e.g., path 420), and the current from the output terminal to power rail of the ground voltage through the transistor Q1 (e.g., path 421).

The voltage difference ΔV caused by the current I through the inductor L can be expressed by formula (1) as follows.

$$Δ V = L \cdot \frac{dI}{d t} \qquad ( 1 )$$

Since the current through path 420 or 421 may be large, the voltage difference ΔV caused by the current I through the inductor L can also be large, resulting in high noise at the power rail of the power supply voltage (e.g., 5V).

In addition, the schematic diagram of the power clamp circuit 410 is shown in FIG. 4B. The power clamp circuit 410 may be a RC-based power clamp circuit, and it may include an RC control circuit 412 and a transistor Q3. The RC control circuit 412 may include a resistor and a capacitor. The resistor may be coupled between the power rail of the power supply voltage (e.g., 5V) and the gate of the transistor Q3. The capacitor may be coupled between the gate of the transistor Q3 and the power rail of the ground voltage (e.g., 0V). Since a voltage of 5V is used, the transistor Q3 may be implemented using the LDMOS technique, and the transistor Q3 may be a BigFET as mentioned.

More specifically, when high noise is induced on the power rail of the power supply voltage, the change in the power supply voltage may be transferred to the gate of the transistor Q3, and may erroneously turn on the transistor Q3 to induce a current I from the power rails of the power supply voltage and the ground voltage through the transistor Q3, resulting in redundant high power loss.

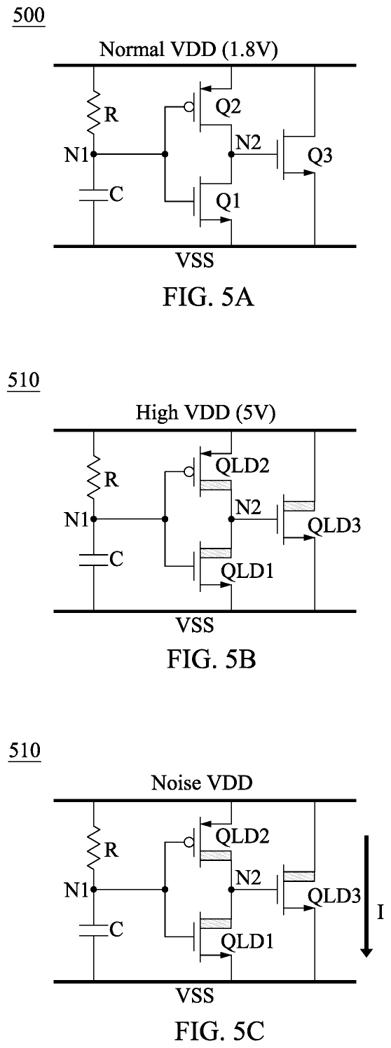

FIG. 5A is a schematic diagram of a power clamp circuit 500 in accordance with an embodiment of the present disclosure. FIG. 5B is a schematic diagram of a power clamp circuit 510 using high power supply voltage in accordance with an embodiment of the present disclosure. FIG. 5C is a schematic diagram of a power clamp circuit 510 with noisy power supply voltage in accordance with an embodiment of the present disclosure. Please refer to FIGS. 5A-5C.

In some embodiments, the power clamp circuit 500 may include transistors Q1 to Q3, a resistor R, and a capacitor C, as shown in FIG. 5A. The resistor R and the capacitor C may form an RC control circuit, and the time constant of R*C may be at us levels. The power clamp circuit 500 may operate with a normal power supply voltage of 1.8V. Thus, transistors Q1 and Q3 can be implemented using the transistor 200 designed for a normal power supply voltage (e.g., 1.8V) shown in FIG. 2A, and the transistor Q2 can also be implemented using a P-type transistor designed for the normal power supply voltage (e.g., 1.8V). When the power clamp circuit 500 is in a normal operation mode, the transistor Q3 is turned off. When the power clamp circuit 500 enters an ESD mode, the transistor Q3 may be turned on to discharge the current induced by an ESD event occurring on the power rail of the power supply voltage VDD. It should be noted that the ESD event may generally occur at nanosecond (ns) level.

In some embodiments, the power clamp circuit 510 shown in FIG. 5B may be obtained by modifying the power clamp circuit 500 to match a high power supply voltage VDD of 5V. For example, the transistors Q1 to Q3 in the power clamp circuit 500 may be replaced by the transistors QLD1 to QLD3 in the power clamp circuit 510. The transistors QLD1 to QLD3 may be implemented using the LDMOS technique. When the high power supply voltage of 5V is applied to the power clamp circuit 510, reliability issues may still occur even though the LDMOS transistors QLD1 to QLD3 are used. For example, the resistor R may be coupled between node N1 and the power rail of the high power supply voltage (e.g., 5V). The highest voltage at node N1 may be 5V, and the voltage difference |VGS| between the gate and the source of the transistor QLD1 will be 5V, which is much greater than the tolerable voltage (e.g., 1.8V) of the gate oxide of the transistor QLD1. As a result, the transistor QLD1 may fail and affect reliability. In addition, the largest voltage difference across the capacitor C2 may be 5V. Since the capacitor C2 in the power clamp circuit 510 and the capacitor C1 in the power clamp circuit 500 may be implemented using the same CMOS manufacturing process, the tolerable voltage of the capacitor C2 may be similar to that of the capacitor C1, which is 1.8V. Thus, the capacitor C2 may fail and affect reliability.

Referring to FIG. 5C, the power clamp circuit 510 may operate with a power supply voltage with high noise, wherein the noise may be at ns levels. For example, assuming that an ESD event of a voltage spike (i.e., high noise) occurs at the power rail of the power supply voltage VDD, the source of the transistor QLD2 may be pulled up to a voltage level of the power supply voltage VDD plus the noise. The gate of the transistor QLD2 is electrically connected to node N1, and the capacitor C is coupled between node 1 and the reference voltage VSS. When the aforementioned ESD event occurs, the voltage level at node N1 may be kept at the power supply voltage VDD by the capacitor C. In this situation, the voltage level of the gate of the transistor QLD2 is lower than that of the source of the transistor QLD2, and the transistor QLD2 will be turned on to pull up the voltage level at node N2 to the power supply voltage VDD plus the noise. Node N2 is the gate of the transistor QLD3. Since the voltage level at the gate of the transistor QLD3 is high enough, the transistor QLD3 will be erroneously turned on by the ESD event to induce a current I from the power rails of the power supply voltage VDD and the reference voltage VSS, resulting in redundant high power loss.

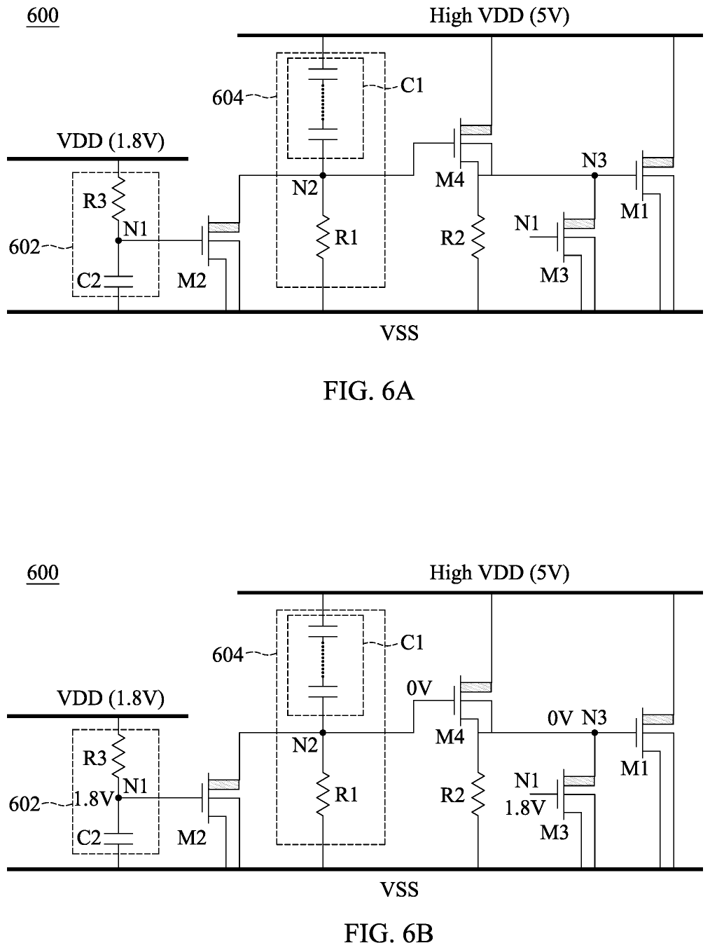

FIG. 6A is a schematic diagram of an ESD clamp circuit 600 in accordance with an embodiment of the present disclosure. FIG. 6B is a diagram illustrating operations of the ESD clamp circuit 600 in accordance with the embodiment of FIG. 6A. Please refer to FIGS. 6A-6B.

In some embodiments, the ESD clamp circuit 600 may operate with two different domains, such as a first power supply voltage of 1.8V (i.e., VDD) and a second power supply voltage of 5V (i.e., high VDD). As depicted in FIG. 6A, the ESD clamp circuit 600 may include RC timer circuits 602 and 604, transistors M1 to M4, and a resistor R2. In some embodiments, the transistor M1 to M4 may be implemented using the LDMOS technique (i.e., M1 to M4 are LDNMOS), and the transistor M1 may be a BigFET. In some other embodiments, the transistors M2 and M3 may be implemented using the transistor 200 shown in FIG. 2A, and the transistor M1 and M4 may be implemented using the LDMOS technique. The total width of the transistor M1 (i.e., BigFET) may be greater than 1000 μm, and the total width of the transistors M2, M3, and M4 may be greater than 50 μm, but the present disclosure is not limited thereto.

The RC timer circuit 602 may include a resistor R3 and a capacitor C2. The resistor R3 may be coupled between node N1 and the first power supply voltage (i.e., VDD), and the capacitor C2 may be coupled between node N1 and the reference voltage VSS. A first RC time constant (R3*C2) of the RC timer circuit 602 may be designed between 100 ns and 1000 μs, but the present disclosure is not limited thereto.

The RC timer circuit 604 may include a plurality of capacitors and a resistor R1. The plurality of capacitors may be connected in series, and may be regarded as an equivalent capacitor C1. For example, these capacitors may be on-chip capacitors implemented using metal-insulator-metal (MIM), metal-oxide-metal (MOM), or metal-oxide-semiconductor (MOS) techniques, but the present disclosure is not limited thereto. The equivalent capacitor C1 may be coupled between the node N2 and the power rail of the second power supply voltage (i.e., high VDD). Taking 3.3V MOM capacitors as an example, two 3.3V MOM capacitors can be stacked (i.e., connected in series) to achieve the equivalent capacitor C1 for 5V applications.

The resistor R1 may be coupled between node N2 and the power rail of the reference voltage VSS. A second RC time constant (R1*C1) of the RC timer circuit 604 may be designed between 10 ns and 100 μs, but the present disclosure is not limited thereto. Furthermore, the first time constant (R3*C2) of the RC timer circuit 602 may be ten times larger than the second time constant (R1*C1) of the RC timer circuit 604, that is, (R3*C2)/(R1*C1)>10.

In some embodiments, as depicted in FIG. 6B, when the ESD clamp circuit 600 is in a normal DC operation mode, the voltage level of the first power supply voltage (i.e., VDD) may be transferred to node N1, so that the voltage at the gate (i.e., node N1) of the transistor M2 is high enough (i.e., 1.8V) to turn on the transistor M2, which may be regarded as a voltage pull-down circuit. Similarly, node N1 may be connected to the gate of the transistor M3, and thus the voltage at the gate of the transistor M3 is also high enough (i.e., 1.8V) to turn on the transistor M3. Thus, the voltage level at node N2 may be pulled down to the reference voltage VSS (i.e., 0V) through the transistor M2, and the voltage at node N3 may be pulled down to the reference voltage VSS (i.e., 0V) through the transistor M3. At this time, the voltage levels at two terminals of the resistor R1 may be substantially equal to the reference voltage VSS, and the voltage levels at two terminals of the resistor R2 may be substantially equal to the reference voltage VSS. Thus, the resistors R1 and R2 may be shunted, and the equivalent resistance R1//R2 for the RC timer circuit 604 significantly decreased. In addition, the gate of the transistor M1 may be electrically connected to the reference voltage VSS through the transistor M3 (i.e., a discharge control circuit). Therefore, even if there is high noise on the power rail of the first power supply voltage VDD (i.e., 1.8V), the transistor M1 (e.g., BigFET) will not be turned on, and thus the ESD clamp circuit 600 is immune thereto.

It should be noted that no matter whether the transistors M1 to M4 are implemented using the LDMOS technique or not, the voltage difference |VGS| between the gate and source of any of the transistors M1 to M4 may be controlled to be within 1.8V to ensure the reliability of the ESD clamp circuit 600.

In some embodiments, when the ESD clamp circuit 600 is in the ESD mode, the first power supply voltage (e.g., VDD) and the second power supply voltage (e.g., high VDD) may not be provided to the ESD clamp circuit 600, and thus the transistors M2 and M3 are turned off. At this time, the transistor M1 (i.e., a discharge circuit) may be controlled by the voltage at its gate (i.e., node N3). When an ESD event occurs on the power rail of the second power supply voltage (e.g., high VDD), a sudden high voltage (e.g., a spike voltage) will be transferred to node N2, so the transistor M4 (e.g., a voltage pull-up circuit) may be turned on and a current may be induced to flow through the transistor M4 and the resistor R2. The resistor R2 may have a resistance between 1002 and 1MΩ, but the present disclosure is not limited thereto. Thus, the voltage level generated by the induced current at node N3 may turn on the transistor M1 (e.g., BigFET), and a discharge current may be induced through the power rails of the second power supply voltage and the reference voltage to discharge the electric charges caused by the ESD event. Therefore, the circuit design of the ESD clamp circuit 600 will not decrease the ESD performance.

In an embodiment, the present disclosure provides a semiconductor device, which includes a first resistance-capacitance (RC) timer circuit, a second RC timer circuit, a voltage pull-down circuit, a voltage pull-up circuit, a discharge circuit, and a discharge control circuit. The first RC timer circuit is coupled between a first power supply voltage and a reference voltage. The second RC timer circuit is coupled between a second power supply voltage and the reference voltage. The voltage pull-down circuit is coupled between the first RC timer circuit and the second RC timer circuit. The voltage pull-up circuit is coupled between the second power supply voltage and the reference voltage through a first resistor. The discharge circuit is coupled between the second power supply voltage and the reference voltage. The discharge control circuit is coupled between a third node and the reference voltage, and controls the discharge circuit using a first voltage generated by the first RC timer circuit.

In another embodiment, the present disclosure provides an electrostatic discharge (ESD) clamp circuit, which includes a first resistance-capacitance (RC) timer circuit, a second RC timer circuit, a first transistor, a second transistor, a third transistor, and a fourth transistor. The first RC timer circuit is coupled between a first power supply voltage and a reference voltage. The second RC timer circuit is coupled between a second power supply voltage and the reference voltage, wherein the second power supply voltage is higher than the first power supply voltage. The first transistor is coupled between the first RC timer circuit and the second RC timer circuit. The second transistor is coupled between the second power supply voltage and the reference voltage through a first resistor. The third transistor is coupled between the second power supply voltage and the reference voltage. The fourth transistor is coupled between a third node and the reference voltage, and configured to control the discharge circuit using a first voltage generated by the first RC timer circuit. A width of the first transistor is greater than that of the second transistor, the third transistor, and the fourth transistor.

In yet another embodiment, the present disclosure provides a electrostatic discharge (ESD) clamp circuit, which includes a first resistance-capacitance (RC) timer circuit, a second RC timer circuit, a first first-type transistor, a second first-type transistor, a first second-type transistor, and a second second-type transistor. The first RC timer circuit is coupled between a first power supply voltage and a reference voltage. The second RC timer circuit is coupled between a second power supply voltage and the reference voltage, wherein the second power supply voltage is higher than the first power supply voltage. The first first-type transistor is coupled between the first RC timer circuit and the second RC timer circuit. The first second-type transistor is coupled between the second power supply voltage and the reference voltage through a first resistor. The second second-type transistor is coupled between the second power supply voltage and the reference voltage. The second first-type transistor is coupled between a third node and the reference voltage, and configured to control the discharge circuit using a first voltage generated by the first RC timer circuit. The first second-type transistor and the second second-type transistor operate with the first power supply voltage, and the first second-type transistor and the second second-type transistor operate with the second power supply voltage.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A semiconductor device, comprising:
a first resistance-capacitance (RC) timer circuit, coupled between a first power supply voltage and a reference voltage;
a second RC timer circuit, coupled between a second power supply voltage and the reference voltage, wherein the second power supply voltage is higher than the first power supply voltage;
a voltage pull-down circuit, coupled between the first RC timer circuit and the second RC timer circuit;
a voltage pull-up circuit, coupled between the second power supply voltage and the reference voltage through a first resistor;
a discharge circuit, coupled between the second power supply voltage and the reference voltage; and
a discharge control circuit, coupled between a third node and the reference voltage, and configured to control the discharge circuit using a first voltage generated by the first RC timer circuit.

2. The semiconductor device of claim 1, wherein the first RC timer circuit comprises a second resistor and a first capacitor, wherein the second resistor is coupled between the first power supply voltage and a first node, and the first capacitor is coupled between the first node and the reference voltage, and the first voltage is generated at the first node.

3. The semiconductor device of claim 2, wherein the second RC timer circuit comprises a third resistor and a second capacitor, wherein the third resistor is coupled between the second power supply voltage and a second node, and the second capacitor is coupled between the second node and the reference voltage, and a second signal is generated at the second node.

4. The semiconductor device of claim 3, wherein the voltage pull-up circuit is controlled by the second signal.

5. The semiconductor device of claim 4, wherein in response to the first voltage being higher than or equal to the first power supply voltage, the discharge control circuit is turned on, wherein in response to the first voltage being lower than the first power supply voltage, the discharge control circuit is turned off.

6. The semiconductor device of claim 1, wherein the discharge circuit, the voltage pull-down circuit, the discharge control circuit, and the voltage pull-up circuit are implemented using a first transistor, a second transistor, a third transistor, and a fourth transistor.

7. The semiconductor device of claim 6, wherein a width of the first transistor is greater than that of the second transistor, the third transistor, and the fourth transistor.

8. The semiconductor device of claim 7, wherein the first transistor and the fourth transistor are laterally diffused metal oxide semiconductor (LDMOS) transistors.

9. The semiconductor device of claim 8, wherein the second transistor and the third transistor are LDMOS transistors.

10. The semiconductor device of claim 8, wherein a voltage difference between a gate and a drain of any of the first transistor, the second transistor, the third transistor, and the fourth transistor is lower than the first power supply voltage.

11. The semiconductor device of claim 3, wherein the second capacitor is an equivalent capacitor of a plurality of capacitors connected in series, and the plurality of capacitors include MIM (metal-insulator-metal) capacitors, MOM (metal-oxide-metal) capacitors, or MOS (metal-oxide-semiconductor) capacitors.

12. The semiconductor device of claim 3, wherein when the semiconductor device is in a normal operation mode, the first voltage at the first node equals to the first power supply voltage to turn on the voltage pull-down circuit and the discharge control circuit; and wherein when the discharge control circuit is turned on, the discharge circuit is turned off.

13. The semiconductor device of claim 3, wherein when the semiconductor device is in an ESD (electrostatic discharge) mode, the first power supply voltage and the second power supply voltage are not provided to the semiconductor device, and the voltage pull-down circuit and the discharge control circuit are turned off.

14. The semiconductor device of claim 13, wherein when an ESD event occurs on a power rail of the second power supply voltage, a spike voltage is transferred to the second node through the second capacitor to turn on the voltage pull-up circuit, and a second voltage is generated at the third node to turn on the discharge circuit to discharge an ESD current caused by the ESD event.

15. An electrostatic discharge (ESD) clamp circuit, comprising:
a first resistance-capacitance (RC) timer circuit, coupled between a first power supply voltage and a reference voltage;
a second RC timer circuit, coupled between a second power supply voltage and the reference voltage, wherein the second power supply voltage is higher than the first power supply voltage;
a first transistor, coupled between the first RC timer circuit and the second RC timer circuit;
a second transistor, coupled between the second power supply voltage and the reference voltage through a first resistor;
a third transistor, coupled between the second power supply voltage and the reference voltage; and
a fourth transistor, coupled between a third node and the reference voltage, and configured to control the discharge circuit using a first voltage generated by the first RC timer circuit,
wherein a width of the first transistor is greater than that of the second transistor, the third transistor, and the fourth transistor.

16. The ESD clamp circuit of claim 15, wherein the first RC timer circuit and the second RC timer circuit have a first RC time constant and a second RC time constant, respectively, and the first RC time constant is ten times greater than the second RC time constant.

17. The ESD clamp circuit of claim 15 wherein the first transistor, the second transistor, the third transistor, and the fourth transistor are laterally diffused metal oxide semiconductor (LDMOS) transistors.

18. An electrostatic discharge (ESD) clamp circuit, comprising:
a first resistance-capacitance (RC) timer circuit, coupled between a first power supply voltage and a reference voltage;
a second RC timer circuit, coupled between a second power supply voltage and the reference voltage, wherein the second power supply voltage is higher than the first power supply voltage;
a first first-type transistor, coupled between the first RC timer circuit and the second RC timer circuit;
a first second-type transistor, coupled between the second power supply voltage and the reference voltage through a first resistor;
a second second-type transistor, coupled between the second power supply voltage and the reference voltage; and
a second first-type transistor, coupled between a third node and the reference voltage, and configured to control the discharge circuit using a first voltage generated by the first RC timer circuit,
wherein the first second-type transistor and the second second-type transistor operate with the first power supply voltage, and the first second-type transistor and the second second-type transistor operate with the second power supply voltage.

19. The ESD clamp circuit of claim 18, wherein the first first-type transistor and the second first-type transistor are laterally diffused metal oxide semiconductor (LDMOS) transistors.

20. The ESD clamp circuit of claim 18, wherein gate oxides of the first transistor, the second transistor, the third transistor, and the fourth transistor have a tolerance voltage equal to the first power supply voltage.
